(19) United States
(12) Patent Application Publication
(10) Pub. No.: US 2026/0068194 A1
(43) Pub. Date: Mar. 5, 2026

(54) CAPACITOR STRUCTURE AND MANUFACTURING METHOD THEREOF

(71) Applicant: TAIWAN SEMICONDUCTOR MANUFACTURING COMPANY LTD., HSINCHU (TW)

(72) Inventors: CHUNG-TING LU, KAOHSIUNG CITY (TW); CHING-YEN LIN, HSINCHU (TW); SHU-CHIN TAI, HSINCHU CITY (TW); YUNG-CHOW PENG, HSINCHU (TW); AKHIL AVILALA, HSINCHU (TW)

(21) Appl. No.: 18/815,884

(22) Filed: Aug. 27, 2024

(51) Int. Cl. H10D 1/68

(52) U.S. Cl. CPC H10D 1/692

(57) ABSTRACT

A capacitor structure is provided. The capacitor structure includes a plurality of electrodes, a first connection electrode, a second connection electrode, and a plurality of dummy electrodes. The electrodes extend in a first direction and are formed in a first metal layer over a substrate. The first and second connection electrodes extend in a second direction perpendicular to the first direction and are formed in a second metal layer different from the first metal layer. The dummy electrodes extend in the second direction and are formed between the first and second connection electrodes in the second metal layer. The first connection electrode is electrically connected to at least two first electrodes of the electrodes, and the second connection electrode is electrically connected to at least one second electrode of the electrodes. The second electrode is disposed between the two first electrodes.

### BACKGROUND

Electronic equipment involving semiconductor devices is essential for many modern applications. Technological advances in materials and design have produced generations of semiconductor devices where each generation has smaller and more complex circuits than the previous generation. Capacitors are used in many applications involving integrated circuits (IC), including for signal conditioning. One of the most commonly used capacitors is the metal-oxide-metal (MOM) capacitor.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A and 1B illustrate a layout of a capacitor unit 10, in accordance with some embodiments of the disclosure.

FIG. 2 is a perspective view of a multi-layer MOM capacitor, in accordance with some embodiments of the disclosure.

FIG. 3 illustrates a layout of a capacitor structure, in accordance with some embodiments of the disclosure.

FIG. 4 illustrates a layout of a capacitor structure, in accordance with some embodiments of the disclosure.

FIGS. 5A and 5B illustrate a layout of a capacitor unit, in accordance with some embodiments of the disclosure.

FIG. 6 illustrates a layout of a capacitor structure, in accordance with some embodiments of the disclosure.

FIG. 7 is a flowchart illustrating a method for manufacturing a capacitor structure, in accordance with some embodiments of the disclosure.

### DETAILED DESCRIPTION

The following disclosure provides many different embodiments, or examples, for implementing different features of the provided subject matter. Specific examples of components and arrangements are described to simplify the disclosure. These are, of course, merely examples and are not intended to be limiting. For example, the formation of a first feature over or on a second feature in the description that follows may include embodiments in which the first and second features are formed in direct contact, and may also include embodiments in which additional features may be formed therebetween. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Various capacitor structures in integrated circuits (ICs) are provided in accordance with various exemplary embodiments. Some variations of embodiments are discussed. Throughout the various views and illustrative embodiments, like reference numbers are used to designate like elements.

Capacitors are widely used in ICs. One of the most commonly used capacitors is the metal-oxide-metal (MOM) capacitor. A MOM capacitor may include a first electrode, a second electrode, and an insulation layer between the first and second electrodes. Each of the first and second electrodes may include multiple fingers and a bus electrically connected to the fingers. A capacitance of the MOM capacitor is proportional to its area and an electric constant, and is inversely proportional to a thickness of the insulation layer.

For low power applications of ICs, since an operating current of an IC is quite small, capacitors with low capacitances are desired for high resolution applications utilizing switched capacitors and successive approximation register analog-to-digital converters (SAR-ADCs), for example.

According to the embodiments of the disclosure, the electrodes functioning as the fingers of the MOM capacitor are formed in a metal layer different from a metal layer of connection electrodes functioning as the buses of the MOM capacitor. Thus, there are no large gaps between the fingers and the buses in a single metal layer of a capacitor structure. Furthermore, a pitch of the fingers is decreased since the fingers are formed in a lower metal layer (e.g., a metal layer Mx of a metal layer stack). Therefore, a capacitance density of the MOM capacitor is increased, e.g., to more than 5000 aF/μm² for small capacitors having capacitance less than or equal to 200 aF.

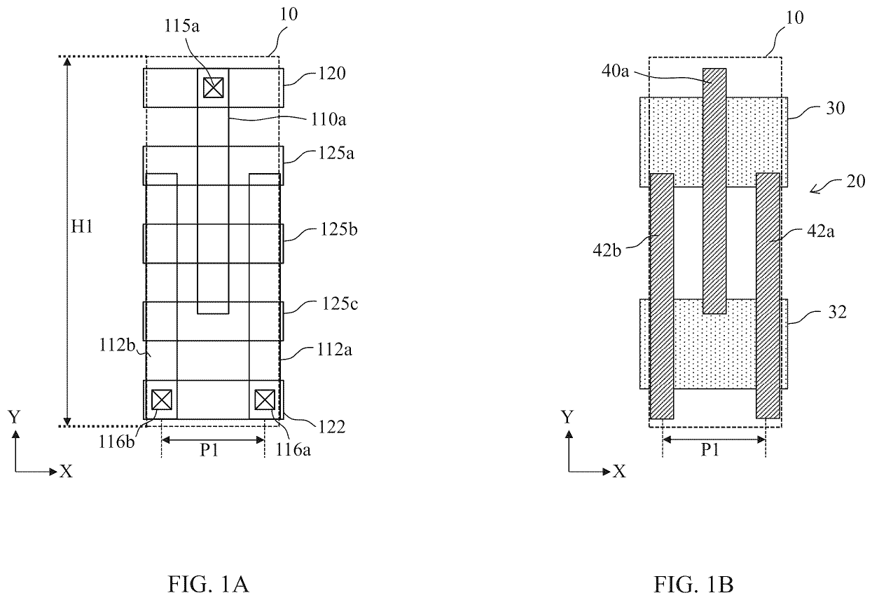

FIGS. 1A and 1B illustrate a layout of a capacitor unit 10, in accordance with some embodiments of the disclosure. Features of the capacitor unit 10 formed in a back-end-of-line (BEOL) structure are shown in FIG. 1A, and features of the capacitor unit 10 formed in a front-end-of-line (FEOL) structure are shown in FIG. 1B. In some embodiments, the capacitor unit 10 is the smallest vertical unit that can be expanded and vertically and/or horizontally abutted in layout to form a capacitor in an IC. In some embodiments, the capacitor unit 10 can be repeatedly stacked from the lower metal layer to an upper metal layer. The capacitor unit 10 has a unit height H1 measured along the Y-axis. The capacitor unit 10 is a small capacitor having capacitance less than or equal to 200 aF.

As shown in FIG. 1A, the electrode 110a and the electrodes 112a and 112b are formed in a metal layer Ma and extend along the Y-axis. In some embodiments, the electrode 110a and the electrodes 112a and 112b have a same length measured along the Y-axis, and a same width measured along the X-axis. A pitch between the electrodes 112a and 112b is P1. Furthermore, a pitch between the electrodes 110a and 112a and a pitch between the electrodes 110a and 112b are respectively one half of the pitch P1. Moreover, the electrodes 110a, 112a and 112b may also be referred to as the fingers in the MOM capacitor. In some embodiments, a minimum number of the fingers in the same metal layer is 3, for example, the electrodes 110a, 112a and 112b of the capacitor unit 10. Furthermore, the outer electrodes 112a and 112b are also referred as the connection fingers of the MOM capacitor that are the buses for abutment, and the inner electrode 110a is the finger of the MOM capacitor sandwiched by the connection fingers.

The connection electrodes 120 and 122 and the dummy electrodes 125a through 125c are formed in a metal layer Mb and extend along the X-axis. The metal layer Mb is disposed over the metal layer Ma. In some embodiments, the metal layer Mb is the metal layer closest to the metal layer Ma. The dummy electrodes 125a through 125c are disposed between the connection electrodes 120 and 122 for shielding with a low metal density (e.g., 20% to 30%). The dummy electrodes 125a through 125c are floating in the capacitor unit 10. A number of the dummy electrodes 125a through 125c is merely illustrative and should not be construed as limiting the disclosure. In some embodiments, a pitch between one dummy electrode and an adjacent dummy electrode (or an adjacent connection electrode) is determined according to a maximum pitch of the metal layer Mb in a design rule for an IC, so as to decrease a coupling effect. In some embodiments, the dummy electrodes 125a through 125c and the connection electrodes 120 and 122 have a same length measured along the X-axis and a same width measured along the Y-axis. Moreover, the connection electrodes 120 and 122 may be referred to as the buses in the MOM capacitor. In this embodiment, the fingers and the buses are not formed in a same metal layer of the capacitor unit 10. In other words, no electrode functioning as the bus of the MOM capacitor is formed in the metal layer Ma.

By disposing the dummy electrodes 125a through 125c in an area between the connection electrodes 120 and 122, the area will not be used for placing unexpected routings (or traces) in the metal layer Mb, and a uniform metal density is provided in the capacitor unit 10. The unexpected routings are placed due to insufficient metal density of the metal layer Mb, which would lead to structural mismatch and affect a capacitance accuracy of the capacitor unit 10. When the capacitance is smaller, a mismatch has a greater impact on the capacitance accuracy.

The electrode 110a is electrically connected to the connection electrode 120 through a via 115a. Similarly, the electrodes 112a and 112b are electrically connected to the connection electrode 122 through vias 116a and 116b, respectively. The connection electrode 120, the via 115a and the electrode 110a form a first electrical conductor of the capacitor unit 10, and the connection electrode 122, the vias 116a and 116b, and the electrodes 112a and 112b form a second electrical conductor of the capacitor unit 10. The electrode 110a partially overlaps the connection electrode 120 and the dummy electrodes 125a through 125c, and the electrodes 112a and 112b partially overlap the connection electrode 122 and the dummy electrodes 125a through 125c. In other words, the electrode 110a does not overlap the connection electrode 122, and the electrodes 112a and 112b do not overlap the connection electrode 120, i.e., no electrode overlaps both the connection electrodes 120 and 122 in the metal layer Ma. Furthermore, all of the electrodes 110a, 112a and 112b partially overlap the dummy electrodes 125a through 125c.

In some embodiments, the connection electrode 122 is a common electrode for connecting to capacitor units 10 in an adjacent row, and the connection electrode 120 is a signal electrode. In some embodiments, the connection electrode 120 is removed when the capacitor unit 10 is a dummy unit. In some embodiments, the connection electrode 120 is also the common electrode for connecting to the capacitor units 10 in the adjacent row.

As shown in FIG. 1B, the active regions 30 and 32 are formed in a substrate 20 and extend along the X-axis. The gate structures 40a, 42a and 42b are formed over the substrate 20 and extend along the Y-axis. In some embodiments, the active regions 30 and 32 are dummy active regions and the gate structures 40a, 42a and 42b are dummy gate structures, and no voltage is applied to the dummy gate structures 40a, 42a and 42b and the dummy active regions 30 and 32. In some embodiments, the active regions 30 and 32 are different types of active regions. For example, the active region 30 is a P-type active region and the active region 32 is an N-type active region.

A pitch between the gate structures 42a and 42b is P1. Furthermore, a pitch between the gate structures 40a and 42a and a pitch between the gate structures 40a and 42b are respectively one half of the pitch P1. Thus, a configuration of the gate structures 40a, 42a and 42b matches a configuration of the electrodes 110a, 112a and 112b of FIG. 1A, which avoids mismatching of the capacitor unit 10 and thereby prevents a negative impact on the capacitance accuracy. In some embodiments, the gate structures 40a, 42a and 42b completely overlap the electrodes 110a, 112a and 112b, respectively, from a top-view perspective. In some embodiments, the connection electrode 120 and the dummy electrode 125a of FIG. 1A partially overlap the active region 30 from a top-view perspective, and the connection electrode 122 and the dummy electrode 125c of FIG. 1A partially overlap the active region 32 from a top-view perspective.

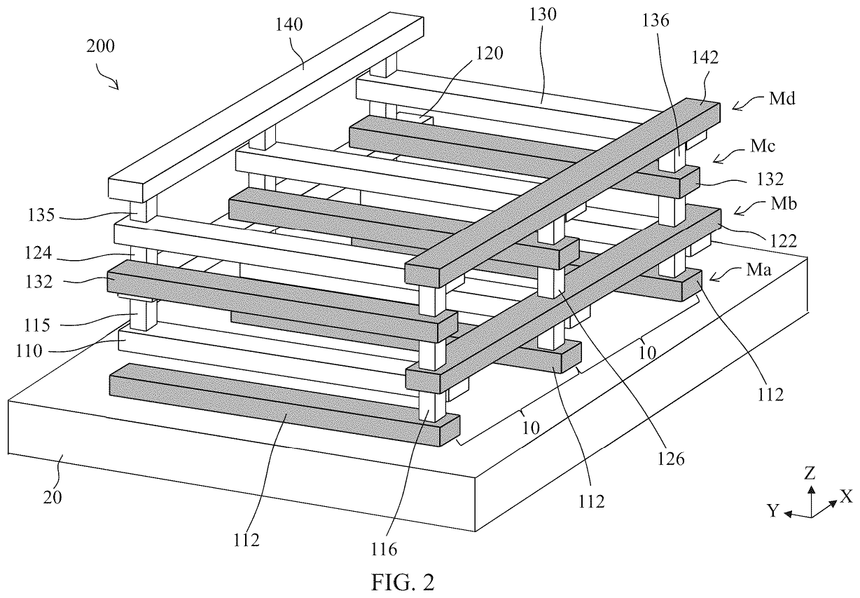

FIG. 2 is a perspective view of a multi-layer MOM capacitor 200, in accordance with some embodiments of the disclosure. The multi-layer MOM capacitor 200 is disposed over the substrate 20. In this embodiment, two capacitor units 10 of FIG. 1A are horizontally abutted, i.e., adjacent along the X-axis, and the two capacitor units 10 share a common electrode 112 located at a junction of the two capacitor units 10. The multi-layer MOM capacitor 200 is formed by stacked and abutting capacitor units 10. Electrode configurations of the metal layers Ma, Mb, Mc and Md are shown in FIG. 2, while dummy electrodes (e.g., 125a through 125c in FIG. 1A) are not shown in FIG. 2. Among the metal layers Ma, Mb, Mc and Md, the metal layer Ma is the metal layer closest to the substrate 20, and the metal layer Md is the metal layer farthest from the substrate 20.

Electrodes 110 of the metal layer Ma are electrically connected to a connection electrode 120 of the metal layer Mb through corresponding vias 115. Electrodes 130 in the metal layer Mc have a configuration same as that of the electrodes 110 of the metal layer Ma. In this embodiment, the electrodes 130 completely overlap the electrodes 110 from a top view, i.e., viewed along the Z-axis. In some embodiments, the electrodes 110 and 130 have a same size in a projection direction along the Z-axis. In some embodiments, the electrodes 130 and the electrodes 110 are staggered from the top view. The connection electrode 120 of the metal layer Mb is electrically connected to the electrodes 130 of the metal layer Mc through corresponding vias 124. The electrodes 130 of the metal layer Mc are electrically connected to a connection electrode 140 of the metal layer Md through corresponding vias 135. In some embodiments, the connection electrodes 120 and 140 have a same size in a projection direction along the Z-axis.

Electrodes 112 of the metal layer Ma are electrically connected to a connection electrode 122 of the metal layer Mb through corresponding vias 116. Electrodes 132 in the metal layer Mc have a configuration same as that of the electrodes 112 of the metal layer Ma. In this embodiment, the electrodes 132 completely overlap the electrodes 112 from a top view, i.e., viewed along the Z-axis. In some embodiments, the electrodes 132 and the electrodes 112 are staggered from the top view. The connection electrode 122 of the metal layer Mb is electrically connected to the electrodes 132 of the metal layer Mc through corresponding vias 126. The electrodes 132 of the metal layer Mc are electrically connected to a connection electrode 142 of the metal layer Md through corresponding vias 136. In some embodiments, the electrodes 112 and 132 have a same size in a projection direction along the Z-axis, and the connection electrodes 122 and 142 have a same size in the projection direction along the Z-axis.

The electrodes 110 and 130, the connection electrodes 120 and 140, and the corresponding vias 115, 124 and 135 form a first electrical conductor of the multi-layer MOM capacitor 200. The electrodes 112 and 132, the connection electrodes 122 and 142, and the corresponding vias 116, 126 and 136 form a second electrical conductor of the multi-layer MOM capacitor 200. In the multi-layer MOM capacitor 200, each finger (e.g., the electrode 110 or 130) of the first electrical conductor forms a sub-capacitor with its neighboring finger (e.g., the electrode 112 or 132) of the second electrical conductor in the same metal layer. A total capacitance of the multi-layer MOM capacitor 200 is equivalent to a sum of the capacitances of the sub-capacitors.

The metal layers Ma through Md are low metal layers close to the substrate 20 and have a small pitch. For example, the metal layers Ma, Mb, Mc and Md of the capacitor unit 10 are metal layers M1, M2, M3 and M4 in a BEOL structure. In some embodiments, the metal layers Ma through Md are a first inter-layer metal (e.g., Mx) of a metal layer stack that has a smaller pitch than a second inter-layer metal (e.g., My) of the metal layer stack, thus increasing a capacitance density (e.g., a capacitance density of greater than 5000 aF/μm²) of small capacitors having capacitance less than or equal to 200 aF. For example, in an application using one-dimensional (1D) small capacitors, a capacitance density can be increased by 5 to 30 times.

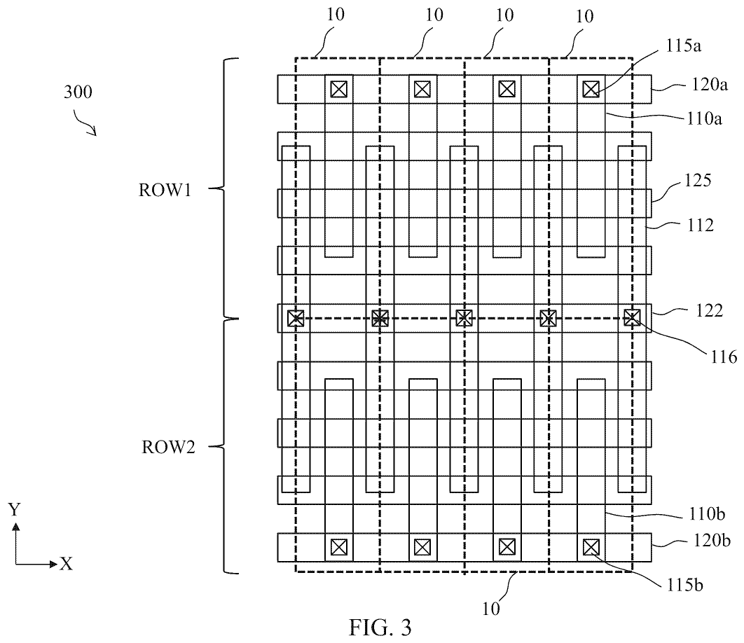

FIG. 3 illustrates a layout of a capacitor structure 300, in accordance with some embodiments of the disclosure. The capacitor structure 300 includes multiple capacitor units 10 arranged in the rows ROW1 and ROW2. In order to simplify the illustration, only features of the metal layers Ma and Mb and features between the metal layers Ma and Mb are shown in FIG. 3. In some embodiments, the capacitor structure 300 is a stacked structure, as shown in FIG. 2.

Each electrode 112 extends along the Y-axis and is a connection finger for abutment of adjacent capacitor units 10. For example, each electrode 112 is shared by two adjacent capacitor units 10 in a same row and adjacent capacitor units 10 in a same column. The electrodes 112 of the capacitor units 10 are electrically connected together through a connection electrode 122 and vias 116. Each of the electrodes 110a and 110b extends along the Y-axis and is disposed between two adjacent electrodes 112. The electrodes 110a in the row ROW1 are electrically connected together through a connection electrode 120a and vias 115a, and the electrodes 110b in the row ROW2 are electrically connected together through a connection electrode 120b and vias 115b.

In the capacitor structure 300, t he capacitor units 10 in the row ROW1 form a first capacitor, and the capacitor units 10 in the row ROW2 form a second capacitor. The connection electrode 120a is electrically connected to the connection electrode 120b through an interconnect structure (not shown). Furthermore, a capacitance provided by the capacitor structure 300 is equal to a sum of the capacitances of the first and second capacitors. The connection electrode 120a connecting the electrode 110a functions as a first electrical conductor of the first capacitor, and the connection electrode 122 connecting the electrodes 112 in the row ROW1 functions as a second electrical conductor of the first capacitor. Similarly, the connection electrode 120b connecting the electrode 110b functions as a first electrical conductor of the second capacitor, and the connection electrode 122 connecting the electrodes 112 in the row ROW2 functions as a second electrical conductor of the second capacitor. The electrodes 110a, 110b and 112 are effective fingers with identical pitches, i.e., the pitch P1 of FIG. 1. In some embodiments, the pitch of the electrodes 110a, 110b and 112 is a smallest pitch specified in a design rule of the metal layer Ma for an IC.

In each of the rows ROW1 and ROW2, multiple dummy electrodes 125 are disposed in the metal layer Mb and between the connection electrodes 120a/120b and 122. The dummy electrodes 125 extend along the X-axis and have same pitches. In some embodiments, a pitch of the dummy electrodes 125 is a largest pitch specified in a design rule of the metal layer Mb for the IC.

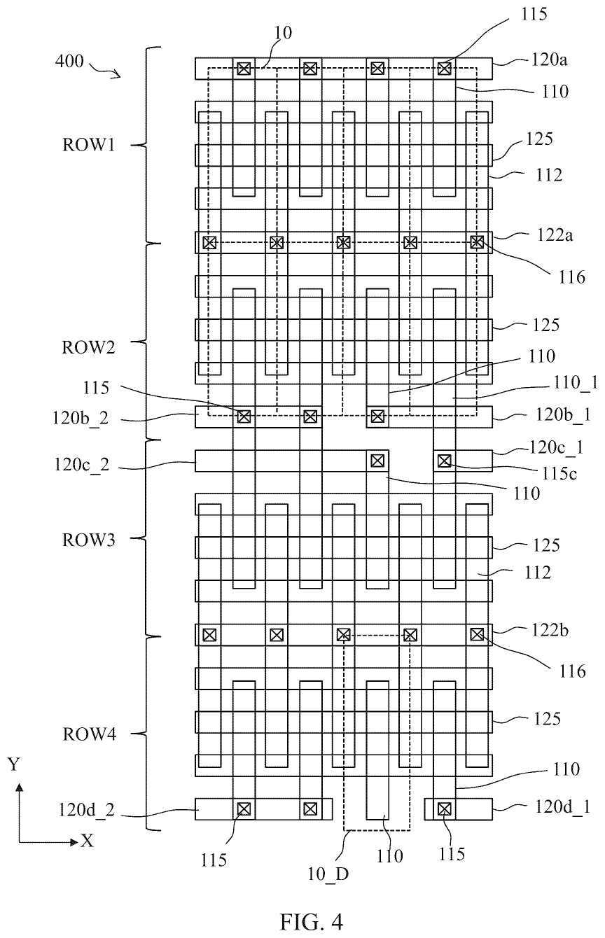

FIG. 4 illustrates a layout of a capacitor structure 400, in accordance with some embodiments of the disclosure. The capacitor structure 400 includes multiple capacitor units 10 arranged in the rows ROW1 through ROW4. In order to simplify the illustration, only features of metal layers Ma and Mb and features between the metal layers Ma and Mb are shown in FIG. 4. In some embodiments, the capacitor structure 400 may be a stacked structure, as shown in FIG. 2.

The capacitor units 10 in the rows ROW1 and ROW2 share a connection electrode 122a, and the capacitor units 10 in the rows ROW3 and ROW4 share a connection electrode 122b. The connection electrode 122a is electrically connected to the electrodes 112 extending in the rows ROW1 and ROW2 through corresponding vias 116, and the connection electrode 122b is electrically connected to the electrodes 112 extending in the rows ROW3 and ROW4 through corresponding vias 116. In other words, the connection electrode 122a is the common electrode for connecting the capacitor units 10 in the rows ROW1 and ROW2, and the connection electrode 122b is the common electrode for connecting the capacitor units 10 in the rows ROW3 and ROW4. In some embodiments, the connection electrode 122a is electrically connected to the connection electrode 122b through an interconnect structure (not shown).

The capacitor structure 400 includes multiple capacitors, and each capacitor is formed by the capacitor units 10 connected to a same signal electrode and a same common electrode. For example, in the row ROW1, the capacitor units 10 electrically connected between the connection electrode 120a (i.e., the signal electrode) and the connection electrode 122a (i.e., the common electrode) form a first capacitor. In the row ROW2, the connection electrodes 120b_1 and 120b_2 are the signal electrodes, and the connection electrode 120b_1 is separated from the connection electrode 120b_2. The capacitor units 10 of the row ROW2 electrically connected between the connection electrode 120b_1 and the connection electrode 122a form a second capacitor. The capacitor unit 10 of the row ROW2 electrically connected between the connection electrode 120b_2 and the connection electrode 122a forms a third capacitor, and the capacitor unit 10 of the row ROW2 electrically connected between a connection electrode 120c_1 and the connection electrode 122a forms a fourth capacitor. Each electrodes 110_1 is an electrode 110 extending from the row ROW2 to the row ROW3. Similarly, the connection electrodes 120c_1 and 120c_2 and the connection electrodes 120d_1 and 120d_2 are signal electrodes. In the row ROW4, the capacitor unit 10 that is not electrically connected to the connection electrodes 120d_1 and 120d_2 is referred as the dummy unit 10_D. In other words, the electrode 110 is floating in the dummy unit 10_D.

By arranging a configuration of the signal electrodes (e.g., the connection electrodes 120a, 120b_1, 120b_2, 120c_1, 120c_2, 120d_1 and 120d_2), the capacitor structure 400 is configured to provide the capacitors with different capacitances, and the capacitance of each capacitor is determined according to a number of the capacitor units 10 connected in parallel.

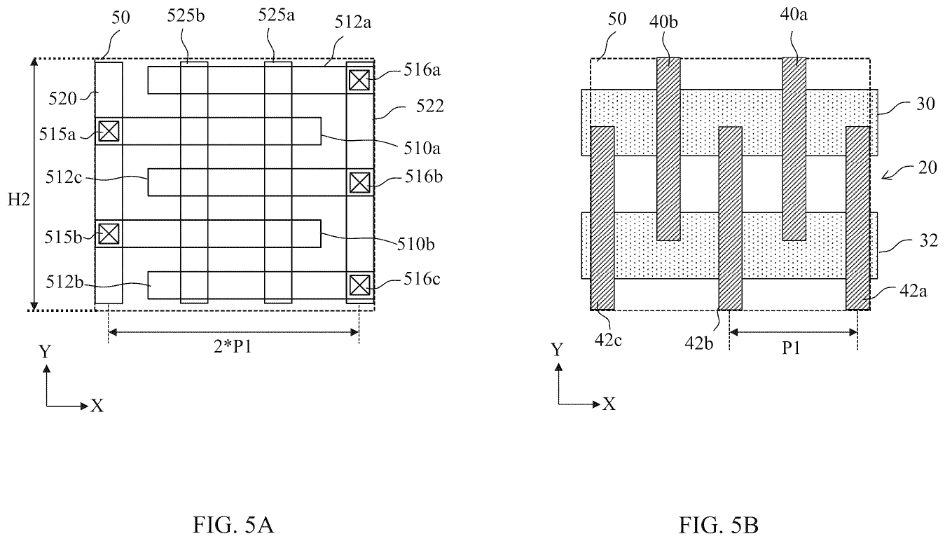

FIGS. 5A and 5B illustrate a layout of a capacitor unit 50, in accordance with some embodiments of the disclosure. Features of the capacitor unit 50 formed in a BEOL structure are shown in FIG. 5A, and features of the capacitor unit 50 formed in a FEOL structure are shown in FIG. 5B. In some embodiments, the capacitor unit 50 is a smallest horizontal unit that can be expanded and vertically and/or horizontally abutted in layout to form a capacitor in an IC. In some embodiments, the capacitor unit 50 can be repeatedly stacked from a lower metal layer to a higher metal layer. The capacitor unit 50 has a unit height H2 measured along the Y-axis. In some embodiments, the unit height H2 is equal to the unit height H1 of FIG. 1A. The capacitor unit 50 is a small capacitor having capacitance less than or equal to 200 aF.

As shown in FIG. 5A, the electrodes 510a and 510b and the electrodes 512a through 512c are formed in a metal layer Me and extend along the X-axis. In some embodiments, the electrodes 510a and 510b and the electrodes 512a through 512c have a same length measured along the X-axis and a same width measured along the Y-axis. A pitch of the electrodes 510a and 510b is equal to a pitch of the electrodes 512a through 512c. Moreover, the electrodes 510a and 510b and the electrodes 512a through 512c may also be referred to as fingers in a MOM capacitor. Furthermore, the outer electrodes 512a and 512b are also referred as connection fingers of the MOM capacitor that are buses for abutment, and the inner electrodes 510a, 510b and 512c are fingers of the MOM capacitor sandwiched by the connection fingers.

The connection electrodes 520 and 522 and the dummy electrodes 525a and 525b are formed in a metal layer Ma and extend along the Y-axis, and the metal layer Ma is disposed over a metal layer Me. In some embodiments, the metal layer Ma is a metal layer closest to the metal layer Me. In some embodiments, a metal layer Mz and the metal layer Ma of the capacitor unit 50 are metal layers M0 and M1 in the BEOL structure. The dummy electrodes 525a and 525b are disposed between the connection electrodes 520 and 522 for shielding with a low metal density (e.g., a metal density of 20% to 30%). The dummy electrodes 525a and 525b are floating in the capacitor unit 50. A number of the dummy electrodes 525a and 525b is merely illustrative and should not be construed as limiting the disclosure. In some embodiments, a pitch between one dummy electrode and an adjacent dummy electrode (or an adjacent connection electrode) is determined according to a maximum pitch of the metal layer Ma in a design rule for an IC. In some embodiments, the dummy electrodes 525a and 525b and the connection electrodes 520 and 522 have a same length measured along the Y-axis and a same width measured along the X-axis. Moreover, the connection electrodes 520 and 522 may also be referred to as buses in the MOM capacitor. In this embodiment, the fingers and the buses are not formed in a same metal layer for the capacitor unit 50. In other words, no electrode functioning as the bus of the MOM capacitor is formed in the metal layer Me.

By disposing the dummy electrodes 525a and 525b in an area between the connection electrodes 520 and 522, the area will not be used for placing unexpected routings (or traces) in the metal layer Ma, and a uniform metal density is provided in the capacitor unit 50. The unexpected routings are placed due to insufficient metal density of the metal layer Ma, which would lead to structural mismatch and negatively affect a capacitance accuracy of the capacitor unit 50. When a capacitance is smaller, mismatch has a greater impact on the capacitance accuracy.

The electrode 510a is electrically connected to the connection electrode 520 through a via 515a, and the electrode 510b is electrically connected to the connection electrode 520 through a via 515b. Similarly, the electrodes 512a through 512c are electrically connected to the connection electrode 522 through vias 516a through 516c, respectively. The electrodes 510a and 510b partially overlap the connection electrode 520 and the dummy electrodes 525a and 525b, and the electrodes 512a through 512c partially overlap the connection electrode 522 and the dummy electrodes 525a and 525b. In other words, the electrodes 510a and 510b do not overlap the connection electrode 522, and the electrodes 512a through 512c do not overlap the connection electrode 520, i.e., no electrode overlaps both the connection electrodes 520 and 522 in the metal layer Me. Furthermore, all of the electrodes 510a and 510b and the electrodes 512a through 512c partially overlap the dummy electrodes 525a and 525b.

In some embodiments, the connection electrode 522 is the common electrode for connecting the capacitor units 50 in an adjacent column, and the connection electrode 520 is the signal electrode. In some embodiments, the connection electrode 520 is removed when the capacitor unit 50 is a dummy unit. In some embodiments, the connection electrode 520 is also the common electrode for connecting the capacitor units 10 in the adjacent column.

As shown in FIG. 5B, the active regions 30 and 32 are formed in a substrate 20 and extend along the X-axis. The gate structures 40a and 40b and the gate structures 42a through 42c are formed over the substrate 20 and extend along the Y-axis. In some embodiments, the active regions 30 and 32 are dummy active regions and the gate structures 40a and 40b and the gate structures 42a through 42c are dummy gate structures, and no voltage is applied to the dummy gate structures and the dummy active regions. In some embodiments, the active regions 30 and 32 are different types of active regions. For example, the active region 30 is a P-type active region and the active region 32 is an N-type active region.

A pitch of the dummy gate structures (i.e., the gate structures 42a through 42c and the gate structures 40a and 40b) is P1. A pitch of the connection electrodes 520 and 522 is a multiple of the pitch P1 of the dummy gate structures. Thus, a configuration of the dummy gate structures and the dummy active regions matches a configuration of the electrodes 510a and 510b and the electrodes 512a through 512c of FIG. 5A, thereby avoiding mismatch of the capacitor unit 50 and reducing negative impact on a capacitance accuracy. In other words, the configurations of the dummy gate structures and the dummy active regions under each capacitor unit 50 are the same.

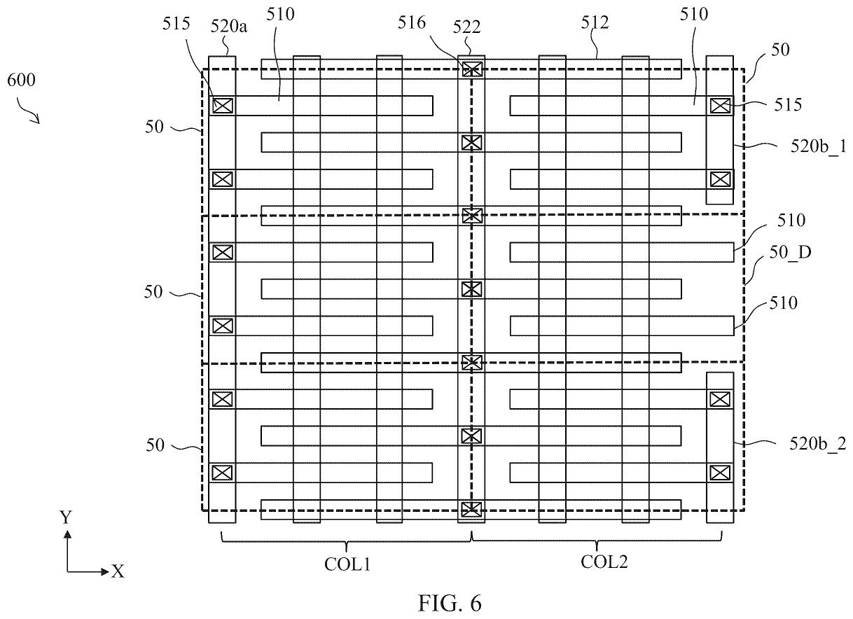

FIG. 6 illustrates a layout of a capacitor structure 600, in accordance with some embodiments of the disclosure. The capacitor structure 600 includes multiple capacitor units 50 arranged in the columns COL1 and COL2. In order to simplify the illustration, only features of metal layers Me and Ma and features between the metal layers Me and Ma are shown in FIG. 6. In some embodiments, the capacitor structure 600 may be a stacked structure, as shown in FIG. 2.

The capacitor units 50 in the columns COL1 and COL2 share a connection electrode 522. The connection electrode 522 is electrically connected to the electrodes 512 extending in the columns COL1 and COL2 through corresponding vias 516. In other words, the connection electrode 522 is a common electrode for connecting the capacitor units 50 in the columns COL1 and COL2.

The capacitor structure 600 includes multiple capacitors, and each capacitor is formed by the capacitor units 50 connected to a same signal electrode and a same common electrode. For example, in the column COL1, the capacitor units 50 electrically connected between a connection electrode 520a (i.e., a signal electrode) and the connection electrode 522 (i.e., the common electrode) form a first capacitor. In the column COL2, the connection electrodes 520b_1 and 520b_2 are signal electrodes, and the connection electrode 520b_1 is separated from the connection electrode 520b_2. The capacitor units 50 of the column COL2 electrically connected between the connection electrode 520b_1 and the connection electrode 522 form a second capacitor. The capacitor unit 50 of the column COL2 electrically connected between the connection electrode 520b_2 and the connection electrode 522 form a third capacitor. The electrodes 512 are the electrodes extending from the column COL1 to the column COL2. In the column COL2, the capacitor unit 50 that is not electrically connected to the connection electrodes 520b_1 and 520b_2 is referred as a dummy unit 50_D. In other words, the electrodes 510 is floating in the dummy unit 50_D.

By arranging a configuration of the signal electrodes (e.g., the connection electrodes 520a, 520b_1 and 520b_2), the capacitor structure 600 is configured to provide the capacitors with different capacitances, and the capacitance of each capacitor is determined according to a number of the capacitor units 50 connected in parallel.

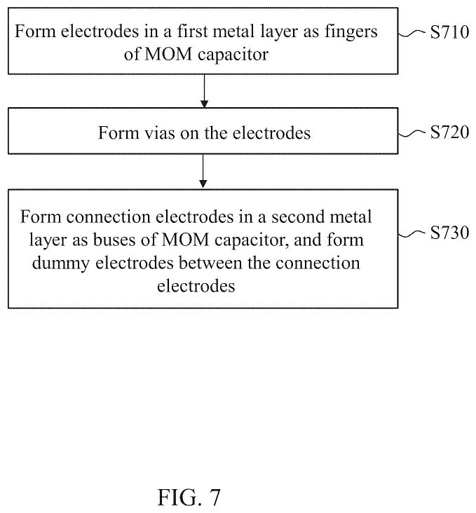

FIG. 7 is a flowchart illustrating a method for manufacturing a capacitor structure, in accordance with some embodiments of the disclosure. It should be understood that the method shown in FIG. 7 is merely an example of many possible embodiments. One of ordinary skill in the art can recognize many variations, alternatives, and modifications. For example, various operations as illustrated in FIG. 7 can be added, removed, replaced, rearranged, or repeated.

In operation S710, the electrodes of the capacitor unit 10 or 50 are formed in a first metal layer with a pitch same as those of first and second fingers corresponding to first and second electrical conductors of a MOM capacitor. The first and second fingers extend along a first direction and are staggered. Furthermore, a space between two outer electrodes among the electrodes is a multiple of a pitch of the dummy gate structures under the electrodes. In operation S720, the vias are formed on the electrodes. In operation S730, the connection electrodes of the capacitor unit 10 or 50 are formed in a second metal layer as the buses of the MOM capacitor, and each bus is electrically connected to the correspond first or second fingers. For example, the connection electrode 120 is a bus electrically connected to the electrodes 110 (e.g., the first fingers) in FIG. 2, and the connection electrode 122 is another bus electrically connected to the electrodes 112 (e.g., the second fingers) in FIG. 2. Furthermore, the dummy electrodes of the capacitor unit 10 or 50 are also formed in the second metal layer. The connection electrodes and the dummy electrodes extend along a second direction perpendicular to the first direction, and the dummy electrodes are disposed between the two adjacent connection electrodes. For example, the dummy electrodes 525a and 525b are disposed between the connection electrodes 520 and 522 in FIG. 5A. Moreover, the connection electrodes are formed and in contact with corresponding vias formed in operation S720, so as to electrically connect to corresponding electrodes.

According to some embodiments, a capacitor structure is provided. The capacitor structure includes a plurality of electrodes, a first connection electrode, a second connection electrode and a plurality of dummy electrodes. The electrodes extend in a first direction and are formed in a first metal layer over a substrate. The first and second connection electrodes extend in a second direction perpendicular to the first direction and are formed in a second metal layer different from the first metal layer. The dummy electrodes extend in the second direction and are formed between the first and second connection electrodes in the second metal layer. The first connection electrode is electrically connected to at least two first electrodes of the electrodes, and the second connection electrode is electrically connected to at least one second electrode of the electrodes. The second electrode is disposed between the two first electrodes.

According to some embodiments, a capacitor structure is provided. The capacitor structure includes a plurality of capacitor units connected in parallel between a first connection electrode and a second connection electrode. The first and second connection electrodes are formed in a first metal layer. Each of the capacitor units includes at least two first electrodes, wherein the first electrodes are formed in a second metal layer, are perpendicular to the first connection electrode, and are electrically connected to the first connection electrode through respective vias; and at least one second electrode, wherein the second electrode is formed in the second metal layer, is perpendicular to the second connection electrode, and is electrically connected to the second connection electrode through a respective via. A plurality of buses of a MOM capacitor include the first and second connection electrodes, and a plurality of fingers of the MOM capacitor include the first and second electrodes. The second metal layer is free of a bus of the MOM capacitor electrically connected to the fingers of the MOM capacitor.

According to some embodiments, a method for manufacturing a capacitor structure is provided. The method includes forming a plurality of electrodes in a first metal layer as a plurality of first fingers and a plurality of second fingers of a metal-oxide-metal (MOM) capacitor, forming a first connection electrode in a second metal layer as a first bus of the MOM capacitor connecting the first fingers, forming a second connection electrode in the second metal layer as a second bus of the MOM capacitor connecting the second fingers, and forming a plurality of dummy electrodes in the second metal layer and between the first and second connection electrodes. The dummy electrodes overlap the first and second fingers from a top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A capacitor structure, comprising:
a plurality of electrodes, extending in a first direction and formed in a first metal layer over a substrate;
a first connection electrode and a second connection electrode, extending in a second direction perpendicular to the first direction and formed in a second metal layer different from the first metal layer; and
a plurality of dummy electrodes, extending in the second direction and formed between the first and second connection electrodes in the second metal layer,
wherein the first connection electrode is electrically connected to at least two first electrodes of the electrodes, and the second connection electrode is electrically connected to at least one second electrode of the electrodes,
wherein the second electrode is disposed between the two first electrodes.

2. The capacitor structure of claim 1, wherein the first connection electrode overlaps the two first electrodes and not overlaps the second electrode from a top view, and the second connection electrode overlaps the second electrode and not overlaps the two first electrodes from a top view.

3. The capacitor structure of claim 1, wherein each of the dummy electrodes overlaps all of the electrodes from a top view.

4. The capacitor structure of claim 1, further comprising:
a plurality of dummy active regions, extending in the second direction and formed in the substrate,
wherein each of the dummy active regions overlaps at least one of the electrodes from a top view.

5. The capacitor structure of claim 4, further comprising:
a plurality of dummy gate structures, extending in the first direction and formed in the substrate,
wherein each of the dummy gate structures overlaps an individual one of the electrodes from a top view.

6. The capacitor structure of claim 1, further comprising:
a plurality of dummy active regions, extending in the first direction and formed in the substrate,
wherein each of the dummy active regions overlaps at least one of the electrodes from a top view.

7. The capacitor structure of claim 6, further comprising:
a plurality of dummy gate structures, extending in the second direction and formed in the substrate,
wherein a pitch of the first and second connection electrodes is a multiple of a pitch of the dummy gate structures.

8. The capacitor structure of claim 1, wherein the first metal layer is a lower metal layer close to the substrate.

9. The capacitor structure of claim 1, wherein the second metal layer is an adjacent metal layer over or under the first metal layer.

10. A capacitor structure, comprising:
a metal-oxide-metal (MOM) capacitor comprising a plurality of capacitor units connected in parallel between a first connection electrode and a second connection electrode, wherein the first and second connection electrodes are formed in a first metal layer,
wherein each of the capacitor units comprises:
at least two first electrodes formed in a second metal layer and perpendicular to the first connection electrode, and electrically connected to the first connection electrode through respective vias; and
at least one second electrode formed in the second metal layer and perpendicular to the second connection electrode, and electrically connected to the second connection electrode through a respective via,
wherein a plurality of buses of the MOM capacitor comprise the first and second connection electrodes, and a plurality of fingers of the MOM capacitor comprise the first and second electrodes,
wherein the second metal layer is free of a bus of the MOM capacitor electrically connected to the fingers of the MOM capacitor.

11. The capacitor structure of claim 10, wherein each of the capacitor units comprises:
a plurality of dummy electrodes between the first and second connection electrodes,
wherein the dummy electrodes extend parallel to the first and second connection electrodes.

12. The capacitor structure of claim 11, wherein the dummy electrodes overlap the first and second electrodes of the capacitor units.

13. The capacitor structure of claim 10, wherein each of the capacitor units comprises:
at least two third electrodes formed in a third metal layer and overlapping the two first electrodes, and electrically connected to the first connection electrode through respective vias; and
at least one fourth electrode formed in the third metal layer and overlapping the second electrode, and electrically connected to the second connection electrode through a respective via,
wherein the first metal layer is disposed between the second and third metal layers.

14. The capacitor structure of claim 10, wherein each of the capacitor units comprises:
a plurality of dummy active regions, extending parallel to the first and second connection electrodes,
wherein each of the dummy active regions overlaps at least one of the first and second electrodes from a top view.

15. The capacitor structure of claim 14, wherein each of the capacitor units comprises:
a plurality of dummy gate structures, extending parallel to the first and second electrodes and formed in the dummy active regions,
wherein each of the dummy gate structures overlaps an individual one of the first and second electrodes from a top view.

16. The capacitor structure of claim 10, wherein each of the capacitor units comprises:
a plurality of dummy active regions, extending parallel to the first and second electrodes,
wherein each of the dummy active regions overlaps at least one of the first and second electrodes from a top view.

17. The capacitor structure of claim 16, wherein each of the capacitor units comprises:
a plurality of dummy gate structures, extending parallel to the first and second connection electrodes and formed in the dummy active regions,
wherein a pitch of the first and second connection electrodes is a multiple of a pitch of the dummy gate structures.

18. A method for manufacturing a capacitor structure, comprising:
forming a plurality of electrodes in a first metal layer as a plurality of first fingers and a plurality of second fingers of a metal-oxide-metal (MOM) capacitor;
forming a first connection electrode in a second metal layer as a first bus of the MOM capacitor connecting the first fingers;
forming a second connection electrode in the second metal layer as a second bus of the MOM capacitor connecting the second fingers; and
forming a plurality of dummy electrodes in the second metal layer and between the first and second connection electrodes,
wherein the dummy electrodes overlap the first and second fingers from a top view.

19. The method of claim 18, further comprising:
forming a plurality of dummy gate structures under the MOM capacitor and parallel to the electrodes,
wherein a pitch of the electrodes is equal to a pitch of the dummy gate structures.

20. The method of claim 18, further comprising:
forming a plurality of dummy gate structures under the MOM capacitor and parallel to the first and second connection electrodes,
wherein a pitch of the first and second connection electrodes is a multiple of a pitch of the dummy gate structures.
